(19) United States
(12) Patent Application Publication
(10) Pub. No.: US 2012/0030451 A1
(43) Pub. Date: Feb. 2, 2012

(54) PARALLEL AND LONG ADAPTIVE INSTRUCTION SET ARCHITECTURE

(75) Inventors: Fong PONG, Mountain View, CA (US); Kwong-Tak CHUI, Cupertino, CA (US); Chun NING, Cupertino, CA (US); Patrick LAU, San Jose, CA (US)

(73) Assignee: Broadcom Corporation, Irvine, CA (US)

(21) Appl. No.: 12/855,981

(22) Filed: Aug. 13, 2010

Related U.S. Application Data
(60) Provisional application No. 61/368,388, filed on Jul. 28, 2010.

(51) Int. Cl. G06F 9/30; H03M 13/09; G06F 11/10; G06F 9/305

(52) U.S. Cl. 712/223; 714/807; 712/220; 712/E09.016; 712/E09.018; 714/E11.032

(57) ABSTRACT

An Parallel and Long Adaptive Instruction Set Architecture (PALADIN) is provided to optimize packet processing. The Instruction Set Architecture (ISA) includes instructions such as aggregate comparison, comparison OR, comparison AND and bitwise instructions. The ISA also includes dedicated packet processing instructions such as hash, predicate, select, checksum and time to live adjust, move header left, post, move header left/right and load/store header/status.

### CROSS-REFERENCE TO RELATED APPLICATIONS

This application claims the benefit of U.S. Provisional Application No. 61/368,388 filed Jul. 28, 2010, which is incorporated herein by reference in its entirety.

### BACKGROUND OF THE INVENTION

1. Field of the Invention

The embodiments presented herein generally relate to packet processing in a communication systems.

2. Background Art

In communication systems, data may be transmitted between a transmitting entity and a receiving entity using packets. A packet typically includes a header and a payload. Processing a packet, for example, by an edge router, typically involves three phases which include parsing, classification, and action. Conventional processors have general purpose Instruction Set Architectures (ISAs) that are not efficient at performing the operations required to process packets.

What is needed are methods and systems to process packets with speed as well as flexible programmability.

### BRIEF DESCRIPTION OF THE DRAWINGS/FIGURES

The accompanying drawings, which are included to provide a further understanding of the invention and are incorporated in and constitute a part of this specification, illustrate embodiments of the invention and together with the description serve to explain the principles of the invention. In the drawings:

FIG. 1A illustrates an example packet processing architecture according to an embodiment.

FIG. 1B illustrates an example packet processing architecture according to an embodiment.

FIG. 1C illustrates an example packet processing architecture according to an embodiment.

FIG. 1D illustrates a dual ported memory architecture according to an embodiment.

FIG. 1E illustrates example custom hardware acceleration blocks according to an embodiment.

FIG. 2 illustrates an example pipeline according to an embodiment of the invention.

FIG. 3 illustrates the stages in pipeline of FIG. 2 in further detail.

FIG. 4 illustrates packet processing logic blocks according to an embodiment of the invention.

FIG. 5 illustrates an example implementation of a comparison OR logic block according to an embodiment of the invention.

FIG. 6 illustrates an example flowchart to process a packet according to an embodiment of the invention.

The present embodiments will now be described with reference to the accompanying drawings. In the drawings, like reference numbers may indicate identical or functionally similar elements.

### DETAILED DESCRIPTION OF THE INVENTION

Processing a packet, for example, by an edge router, typically involves three phases which include parsing, classification, and action. In the parsing phase, the type of packet is determined and its headers are extracted. In the classification phase, the packet is classified into flows where packets in the same flow share the same attributes and are processed in a similar fashion. In the action phase, the packet may be accepted, modified, dropped or re-directed according to the classification results. Packet processing that is performed solely by a conventional processor having a conventional ISA (such as a MIPS®, AMD® or INTEL® processor) can be somewhat slow, especially if the packets require customized processing. A conventional processor is relatively lower in cost. However, the drawback of using a conventional processor to process packets is that it is typically slow at processing packets because its associated ISA is not optimized with instructions to aid in packet processing. Provided herein is a Parallel and Long Adaptive Instruction Set Architecture (PALADIN) that is designed to speed up packet processing. The instructions described herein allow for complex packet processing operations to be performed with relatively fewer instructions and clock cycles. This reduces code density while also speeding up packet processing times. For example, complex if-then-else selections, predicate/select operations, data moving operations, header and status field modifications, checksum modifications etc. can be performed with fewer instructions using the ISA provided herein.

In another example, all aspects of packet processing may be performed solely by custom dedicated hardware. However, the drawback of using solely custom hardware is that it is very expensive to customize the hardware for different types of packets. Solely using custom hardware for packet processing is also very area intensive in terms of silicon real estate and is not adaptive to changing packet processing requirements.

The embodiments presented herein provide both flexible processing and speed by using packet processors with an ISA dedicated to packet processing in conjunction with hardware acceleration blocks. This allows for the flexibility offered by a programmable processor in conjunction with the speed offered by hardware acceleration blocks.

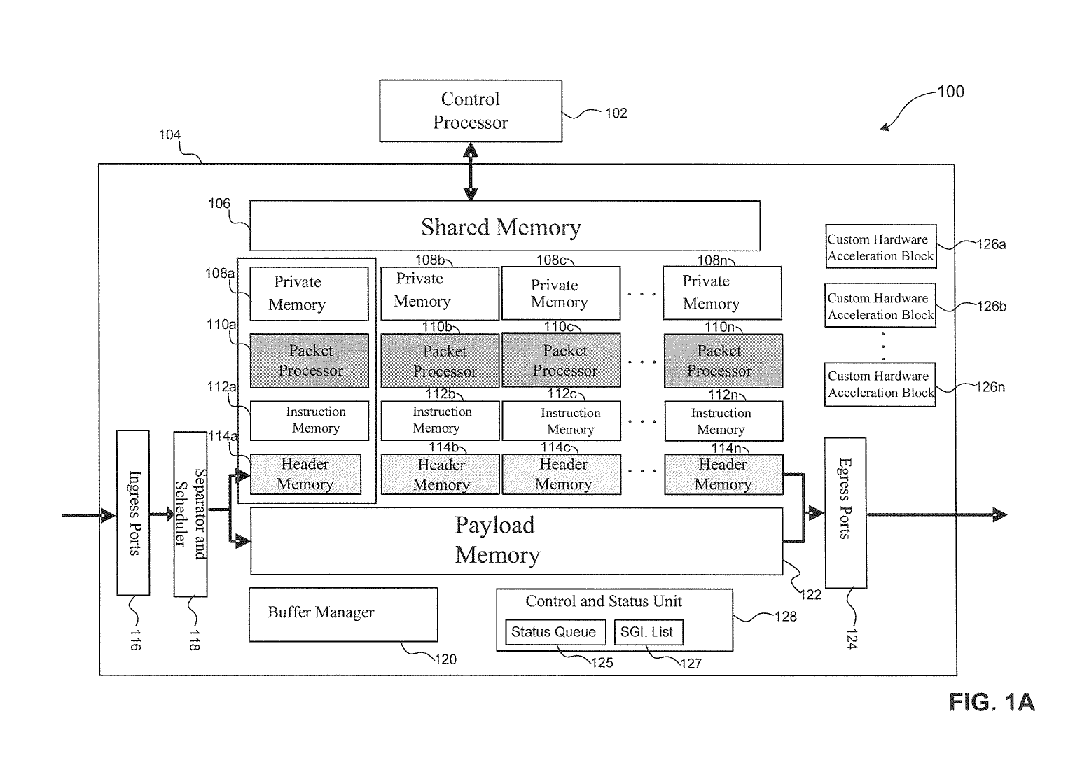

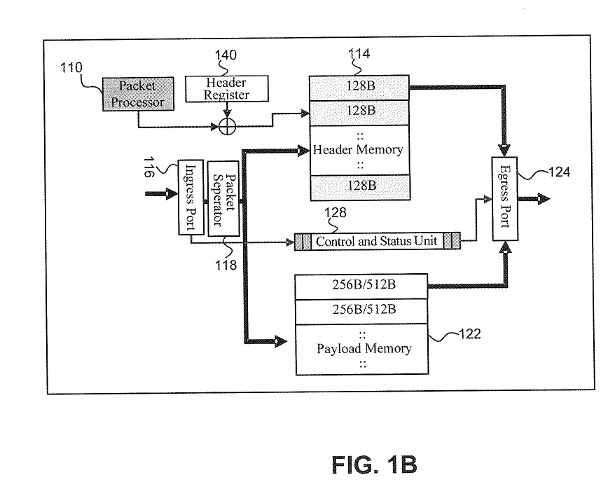

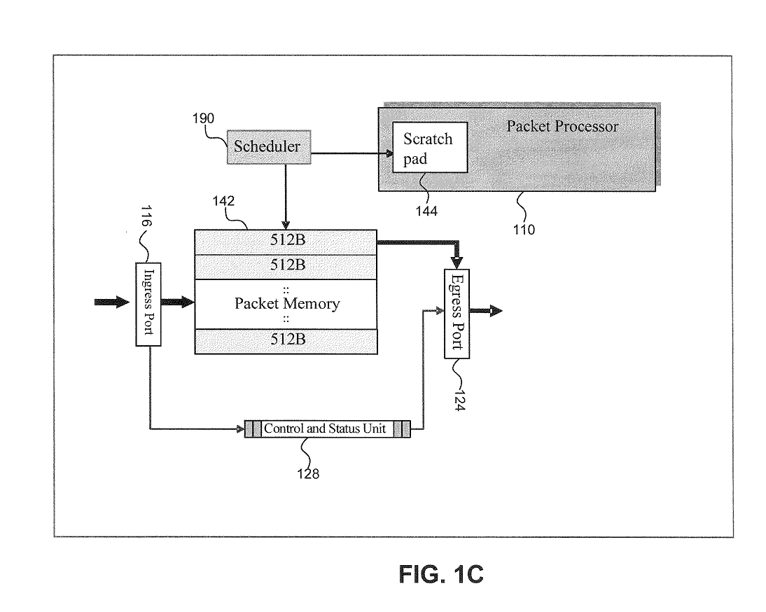

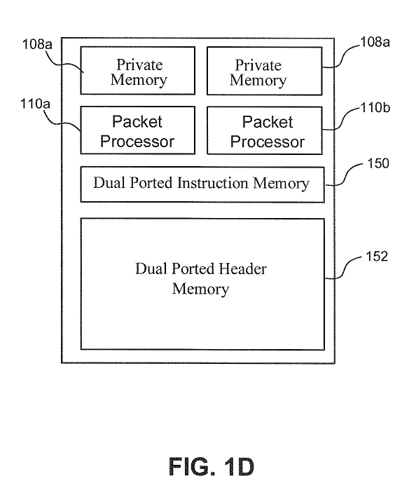

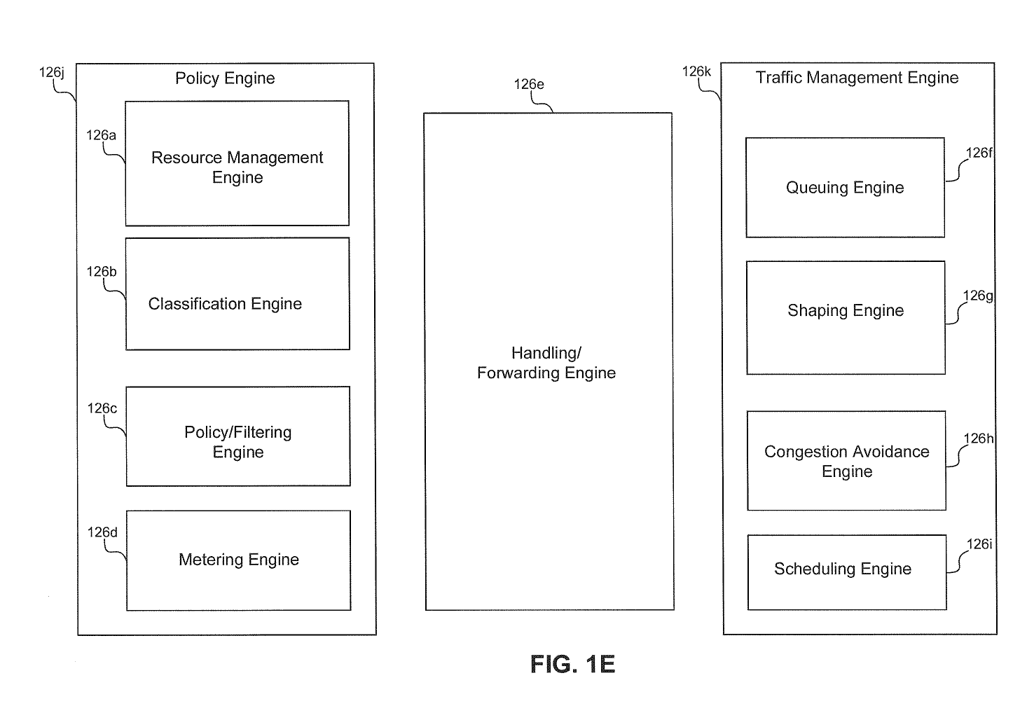

FIG. 1A illustrates an example packet processing architecture 100 according to an embodiment. Packet processing architecture 100 includes a control processor 102 and a packet processing chip 104. Packet processing chip 104 includes shared memory 106, private memories 108a-n, packet processors 110a-n, instruction memories 112a-n, header memories 114a-n, payload memory 122, ingress ports 116, separator and scheduler 118, buffer manager 120, egress ports 124, control and status unit 128 and custom hardware acceleration blocks 126a-n. It is to be appreciated that n is au arbitrary number and may vary based on implementation. In an embodiment, packet processing architecture 100 is on a single chip. In an alternate embodiment, packet processing chip 104 is distinct from control processor 102 which is on a separate chip. Packet processing architecture 100 may be part of any telecommunications device, including but not limited to, a router, an edge router, a switch, a cable modem and a cable modem headend.

In operation, ingress ports 116 receive packets from a packet source. The packet source may be, for example, a cable modem headend or the internet. Ingress ports 116 forward received packets to separator and scheduler 118. Each packet typically includes a header and a payload. Separator and scheduler 118 separates the header of each incoming packet from the payload. Separator and scheduler 118 stores the header in header memory 114 and stores the payload in payload memory 122. FIG. 1B further describes the separation of the header and the payload.

FIG. 1B illustrates an example architecture to separate a header from a payload of an incoming packet according to an embodiment. When a new packet arrives via one of ingress ports 116, a predetermined number of bytes, for example 96 bytes, representing a header of the packet are pushed into an available buffer in header memory 114 by separator and scheduler 118. In an embodiment, each buffer in header memory buffer 114 is 128 bytes wide. 32 bytes may be left vacant in each buffer of header memory 114 so that any additional header fields, such as Virtual Local Area Network (VLAN) tags may be inserted to the existing header by packet processor 110. Status data, such as context data and priority level, of each new packet may be stored in a status queue 125 in control and status unit 128. Status queue 127 allows packet processor 110 to track and/or change the context of incoming packets. After processing a header of incoming packets, control and status data for each packet is updated in the status queue 125 by a packet processor 110.

Still referring to FIG. 1B, each packet processor 110 may be associated with a header register 140 which stores an address or offset to a buffer in header memory 114 that is storing a current header to be processed. In this example, packet processor 110 may access header memory 114 using an index addressing mode. To access a header, a packet processor 110 specifies an offset value indicated by header register 140 relative to a starting address of buffers in header memory 114. For example, if the header is stored in the second buffer in header memory 114, then header register 140 stores an offset of 128 bytes.

FIG. 1C illustrates an alternate architecture to store the packet according to an embodiment. In the example in FIG. 1C, each packet processor 110 has 128 bytes of dedicated scratch pad memory 144 that is used to store a header of a current packet being processed. In this example, there is a single packet memory 142 that is a combination of header memory 114 and payload memory 122. Upon receiving a packet from an ingress port 116, scheduler 190 stores the packet in a buffer in packet memory 142. Scheduler 190 also stores a copy of the header of the received packet in the scratch pad memory 144 internal to packet processor 110. In this example, packet processor 110 processes the header in its scratch pad memory 144 thereby providing extra speed since it does not have to access a header memory 114 to retrieve or store the header.

Still referring to FIG. 1C, upon completion of header processing, scheduler 190 pushes the modified header in the scratch pad memory 144 of packet processor 110 into the buffer storing the associated packet in packet memory 142, thereby replacing the old header with the modified header. In this example, each buffer in packet memory 142 may be 512 bytes. For packets longer than 512 bytes, a scatter-gather-list (SGL) 127 (as shown in FIG. 1A) is used to keep track of parts of a packet that are stored across multiple buffers. The first buffer that a packet is stored in has a programmable offset. In the present example, a received packet may be stored at a starting offset of 32 bytes. The starting 32 bytes of the first buffer may be reserved to allow packet processor 110 to expand the header, for example for VLAN tag additions. If the packet is to be partitioned across multiple buffers, then SGL 127 tracks which buffers are storing which part of the packet. The byte size mentioned herein is only exemplary, as one skilled in the art would know that other byte sizes could be used without deviating from the embodiments presented herein.

Referring now to FIG. 1A, separator and scheduler 118, assigns a header of an incoming packet to a packet processor 110 based on availability and load level of the packet processor 110. In an example, separator and scheduler 118 may assign headers based on the type or traffic class as indicated in fields of the header. In an example, for a packet type based allocation scheme, all User Datagram Protocol (UDP) packets may be assigned to packet processor 110a and all Transmission Control Protocol (TCP) packets may be assigned to packet processor 110b. In another example, for a traffic class based allocation scheme, all Voice over Internet Protocol (VoIP) packets may be assigned to packet processor 110c and all data packets may be assigned to packet processor 110d. In yet another example, packets may be assigned by separator and scheduler 118 based on a round-robin scheme, based on a fair queuing algorithm or based on ingress ports from which the packets are received. It is to be appreciated that the scheme used for scheduling and assigning the packets is a design choice and may be arbitrary. Separator and scheduler 118 knows the demarcation boundary of a header and a payload within a packet based on the protocol a packet is associated with.

Still referring to FIG. 1A, upon receiving a header from separator and scheduler 118 or upon retrieving a header from a header memory 114 as indicated by separator and scheduler 118, processor 110a parses the header to extract data in the fields of the header. A packet processor 110 may also modify the packet. When a custom acceleration hardware block 126 is required to perform a desired operation on a packet, the packet processor 110 may assign the operation to the custom acceleration hardware block 126 by sending the header fields of the packet to the custom hardware acceleration block 126 for processing. For example, if a high performance policy engine 126j (see FIG. 1E) is to be used, packet processor 110a may send data in header fields, including but not limited to, receive port, transmit port, Media Access Control Source Address (MAC-SA), Internet Protocol (IP) source address, IP destination address session identification etc. to the policy engine 126j (see FIG. 1E) for processing. In another example, if the data in the header fields indicates that the packet is an encrypted packet, packet processor 110 sends the header to control processor 102 or to a custom hardware accerleration block 126 that is dedicated to cryptographic processing (not shown).

Control processor 102 may selectively process headers based on instructions from the packet processor 110, for example, for encrypted packets. Control processor 102 may also provide an interface for instruction code to be stored in instruction memory 112 of the packet processor and an interface to update data in tables in shared memory 106 and/or private memory 108. Control processor may also provide an interface to read status of components in chip 104 and to provide control commands components of chip 104.

In a further example, packet processor 110, based on a data rate of incoming packets, determines whether packet processor 110 itself or one or more of custom hardware acceleration blocks 126 should process the header. For example, for low incoming data rate or a low required performance level, packet processor 110 may itself process the header. For high incoming data rate or a high required performance level, packet processor 110 may offload processing of the header to one or more of custom hardware acceleration blocks 126. In the event that packet processor 110 processes a packet header itself instead of offloading to custom hardware acceleration blocks 126, packet processor 110 may execute software versions of the custom hardware acceleration blocks 126.

It is a feature of embodiments presented herein, that packet processors 110a-n may continue to process incoming headers while a current header is being processed by custom hardware acceleration block 126 or control processor 102 thereby allowing for faster and more efficient processing of packets. In an embodiment, incoming packet traffic is assigned to packet processors 110a-n by separator and scheduler 118 based on a round robin scheme. In another embodiment, incoming packet traffic is assigned to packet processors 110a-n by separator and scheduler 118 based on availability of a packet processor 110. Multiple packet processors 110a-n also allow for scheduling of incoming packets based on, for example, priority and/or class of traffic.

Custom hardware acceleration blocks 126 are configured to process the header received from packet processor 110 and generate header modification data. Types of hardware acceleration blocks 126 include but are not limited to, (see FIG. 1E) policy engine 126j that includes resource management engine 126a, classification engine 126b, filtering engine 126c and metering engine 126d; handling and forwarding engine 126e; and traffic management engine 126k that includes queuing engine 126f, shaping engine 126g, congestion avoidance engine 126h and scheduling engine 126i. Custom hardware acceleration blocks may also include a micro data mover (uDM—not shown) that moves data between shared memory 106, private memory 108, instruction memory 112, header memory 114 and payload memory 122. It is also to be noted that custom hardware acceleration blocks 126 are different from generic processors, since they are hard wired logic operations. Custom hardware acceleration blocks 126a-k may process headers based on one or more of incoming bandwidth requirements or data rate requirements, type, priority level, and traffic class of a packet and may generate header modification data. Types of the packets may include but are not limited to: Ethernet, Internet Protocol (IP), Point-to-Point Protocol Over Ethernet (PPPoE), UDP, and TCP. The traffic class of a packet may be, for example, VoIP, File Transfer Protocol (FTP), Hyper Text Transfer Protocol (80), video, or data. The priority of the packet may be based on, for example, the traffic class of the packet. For example, video and audio data may be higher priority than FTP data. In alternate embodiments, the fields of the packet may determine the priority of the packet. For example a field of the packet may indicate the priority level of the packet.

Header modification data generated by custom acceleration blocks 126 is sent back to the packet processor 110 that generated the request for hardware accelerated processing. Upon receiving header modification data from custom hardware acceleration blocks 126, packet processor 110 modifies the header using the header modification data to generate a modified header. Packet processor 110 determines the location of payload associated with the modified header based on data in control and status unit 128. For example, status queue 125 in control and status unit 128 may store an entry that identifies location of a payload in payload memory 122 associated with the header processed by packet processor 110. Packet processor 110 combines the modified header with the payload to generate a processed packet. Packet processor 110 may optionally determine the egress port 124 from which the packet is to be transmitted, for example from a lookup table in shared memory 106 and forward the processed packet to egress port 124 for transmission. In an alternate embodiment, egress ports 124 determine the location of the payload in the payload memory 122 and the location of a modified header, stored in header memory 114 by a packet processor 110, based on data in the control and status unit 128. One or more egress ports 124 combine the payload from payload memory and the header from header memory 114 and transmit the packet.

In an example, a shared memory architecture may be utilized in conjunction with a private memory architecture. Shared memory 106 speeds up processing of packets by packet processing engines 110 and/or custom hardware acceleration logic 126 by storing commonly used data structures. In the shared memory architecture, each of packet processors 110a-n share the address space of shared memory 106. Shared memory 106, may be used to store, for example, tables that are commonly used by packet processors 110 and/or custom hardware acceleration logic 126. For example, shared memory 106 may store Address Resolution Lookup (ARL) table for Layer-2 switching, Network Address Translation (NAT) table for providing a single virtual IP address to all systems in a protected domain by hiding their addresses, and quality of service (QoS) tables that specify the priority, bandwidth requirement and latency characteristics of classified traffic flows or classes. Shared memory 106 allows for a single update of data as opposed to individually updating data in private memory 108 of each of packet processors 110a-n. Storing commonly shared data structures in shared memory 126 circumvents duplicate updates of data structures for each packet processor 110 in associated private memories 108, thereby saving the extra processing power and time required for multiple redundant updates. For example, a shared memory architecture offers the advantage of a single update to a port mapping table in shared memory 106 as opposed to individually updating each port mapping table in each of private memories 108.

Control and status unit 128 stores descriptors and statistics for each packet. For example, control and status unit 128 engine stores a location of a payload in payload memory 122 and a location of an associated header in header memory 114 for each packet. It also stores the priority levels for each packet and which port the packet should be sent from. Packet processor 110 updates packet statistics, for example, the priority level, the egress port to be used, the length of the modified header and the length of the packet including the modified header. In an example, the status queue 125 stores the priority level and egress port for each packet and the scatter gather list (SGL) 127 stores the location of the payload in payload memory 122, the location of the associated modified header in header memory 114, the length of the modified header and the length of the packet including the modified header.

Embodiments presented herein also offer the advantages of a private memory architecture. In the private memory architecture, each packet processor 110 has an associated private memory 108. For example, packet processor 110a has an associated private memory 108a. The address space of private memory 108a is accessible only to packet processor 110a and is not accessible to packet processors 110b-n. A private address space grants each packet processor 110, a distinct, exclusive address space to store data for processing incoming headers. The private address space offers the advantage of protecting core header processing operations of packet processors 110 from corruption. In an embodiment, custom hardware acceleration blocks 126a-m have access to private address space of each packet processor 110 in private memory 108 as well as to shared memory address space in shared memory 106 to perform header processing functions.

Buffer manager 120 manages buffers in payload memory 122. For example, buffer manager 120 indicates, to separator and scheduler 118, how many and which packet buffers are available for storage of payload data in payload memory 122. Buffer manger 120 may also update control and status unit 128 as to a location of a payload of each packet. This allows control and status unit 128 to indicate to packet processor 110 and/or egress ports 124 where a payload associated with a header is located in payload memory 122.

In an embodiment, each packet processor has an associated single ported instruction memory 112 and a single ported header memory 114 as shown in FIG. 1A. In an alternate embodiment, as shown in FIG. 1D, a dual ported instruction memory 150 and a dual ported header memory 152 may be shared by two processors. Sharing a dual ported instruction memory 150 and a dual ported header memory 152 allows for savings in memory real estate if both packet processors 110a and 110b share the same instruction code and process the same headers in conjunction.

In an embodiment, each packet processor 110 is associated with a register file that includes 16 registers denoted as r0 to r15. Register r0 is reserved and reads to r0 always return 0. Register r0 cannot be written to since its default value is always 0. Each packet processor 110 is also associated with eight 1-bit boolean registers, denoted as br0 to br7. Register br7 is reserved and always has a logic value of 1.

FIG. 1E illustrates example custom hardware acceleration blocks 126a-k according to an embodiment. Policy engine 126j includes resource management engine 126a, classification engine 126b, filtering engine 126c and metering engine 126d. Traffic management engine 126k includes queuing engine 126f, shaping engine 126g, congestion avoidance engine 126h and scheduling engine 126i.

Resource management engine 126a determines the number of buffers in payload memory 122 that may be reserved by a particular flow of incoming packets. Resource management engine 126a may determine the number of buffers based on the priority of the packet and/or the type of flow. Resource management engine 126a adds to an available buffer count as buffers are released upon transmission of a packet. Resource management engine 126a also deducts from the available buffer count as buffers are allocated to incoming packets.

Classification engine 126b determines the class of the packet based on header fields, including but not limited to, receive port, Media Access Control Source Address (MAC-SA), Media Access Control Destination Address (MAC-DA), Internet Protocol (IP) source address, IP destination address, DSCP code, VLAN tags, Transport Protocol Port Numbers and etc. The classification engine may also label the packet by a service identification flow (SID) and may determine/change the quality of service (QoS) parameters in the header of the packet.

Filtering engine 126c is a firewall engine that determines whether the packet is to be processed or to be dropped.

Metering engine 126d determines the amount of bandwidth that is to be allocated to a packet of a particular traffic class. For example, metering engine 126d, based on lookup tables in shared global memory 106, determines the amount of bandwidth that is to be allocated to a packet of a particular traffic class. For example, video and VoIP traffic may be assigned greater bandwidth. When an ingress rate of packets belonging to a particular traffic class exceeds an allocated bandwidth for that traffic class, the packets are either dropped by metering engine 126d or are marked by metering engine 126d as packets that are to be dropped later on if congestion conditions exceed a certain threshold.

Handling/forwarding engine 126e determines the quality of service, IP (Internet Protocol) precedence level, transmission port for a packet, and the priority level of the packet. For example, video and voice data may be assigned a higher level of priority than File Transfer Protocol (FTP) or data traffic.

Queuing engine 126f determines a location in a transmission queue of a packet that is to be transmitted.

Shaping engine 126g determines the amount of bandwidth to be allocated for each packet of a particular flow.

Congestion avoidance engine 126h avoids congestion by dropping packets that have the lowest priority level. For example, packets that have been marked by a Quality of Service (QoS) meter as having low priority may be dropped by congestion avoidance engine 126h. In another embodiment, congestion avoidance engine 126h delays transmission of low priority packets by buffering them, instead of dropping low priority packets, to avoid congestion.

Scheduling engine 126i arranges packets for transmission in the order of their priority. For example, if there are three high priority packets and one low priority packet, scheduling engine 126i may transmit the high priority packets before the low priority packet.

According to embodiments presented herein, a customized ISA is provided for packet processors 110. The customized ISA provides instructions that allow for fast and efficient processing of packets.

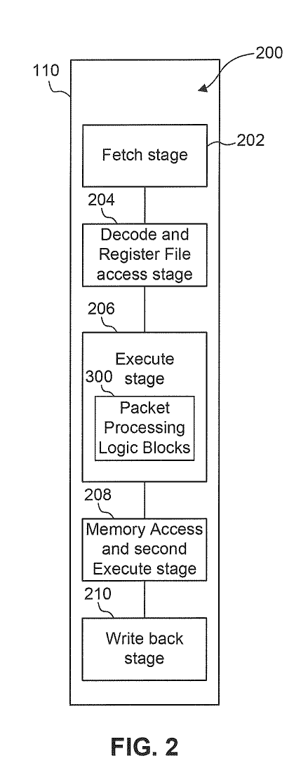

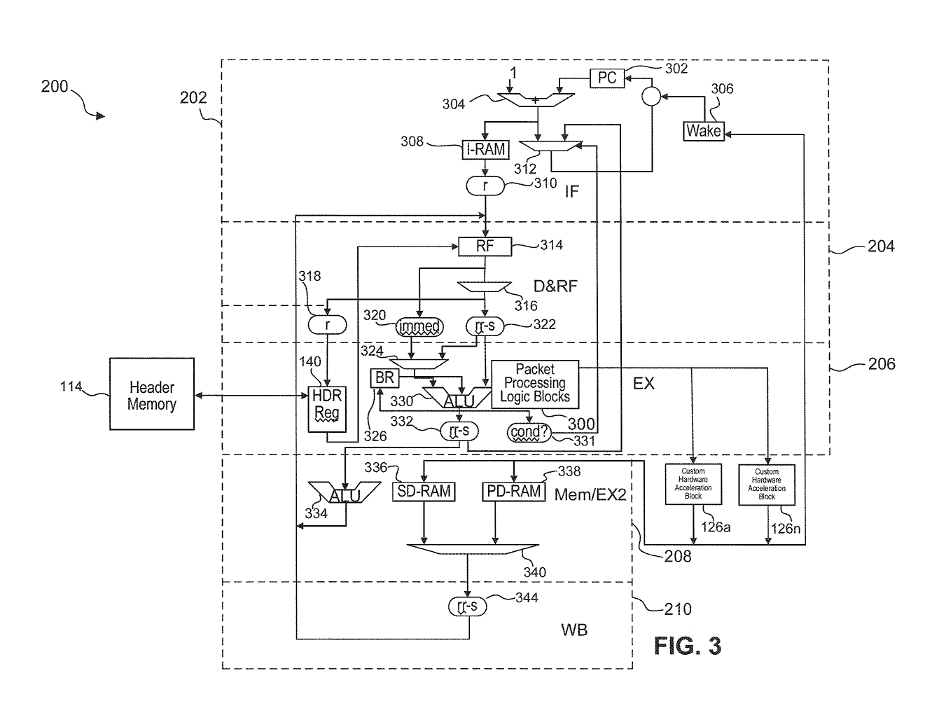

FIG. 2 illustrates an example pipeline 200 for each packet processor 110 according to an embodiment of the invention. Pipeline 200 includes the stages: instruction fetch stage 202, decode and register file access stage 204, execute stage 206 (also referred to as “execution unit” herein), memory access and second execute stage 208 and write back stage 210. In an embodiment, these are hardware implemented stages of processors 110, as will be shown in FIG. 3.

In fetch stage 202, an instruction is fetched from, for example, instruction memory 112. In decode stage 204, the fetched instruction is decoded and, if required, operand values are retrieved from a register file. In the execute stage 206, the instruction fetched in fetch stage 202 is executed. According to an embodiment of the invention, packet processing logic blocks 300 within execute stage 206 execute custom instructions designed to aid in packet processing as will be described further below.

In the memory access and second execute stage 208, memory is either accessed for loading or storing data. In memory access and second execute stage 208, further operations, such as resolving branch conditions, may also be performed. In write-back stage 210, values are written back to the register file. Each of the stages in pipeline 200 are further described with reference to FIG. 3 below.

FIG. 3 further illustrates the stages in pipeline 200.

Fetch stage 202 includes a program counter (pc) 302, adder 304, “wake” logic 306, instruction Random Access Memory (I-RAM) 308, register 310 and mux 312. In fetch stage 202, program counter 302 keeps track of which instruction is to be executed next. Adder 304 increments the program counter 302 by 1 after each clock cycle to point to a next instruction in program code stored in, for example, I-RAM 308. In an example, instructions (also referred to as “program code” herein) may be stored in I-RAM 308 from instruction memory 112. Mux 312 determines whether the address specified by an incremented value for program counter from adder 304 or an address specified by a jump value as determined in execution stage 206 is to be used to update the program counter 302. Based on the value in program counter 302, instruction ram 308 fetches the corresponding instruction. The fetched instruction is stored in register 310. Based on fields in certain instructions as described below, “wake” logic 306 stalls pipeline 200 while waiting for a custom hardware acceleration block 126 to deliver the results. It is to be appreciated that wake logic 306 is programmable and stalls the pipeline 200 only when instructed to.

Decode and register file access stage 204 includes, register file 314, mux 316, register 318, register 320 and register 322. In decode and register file access stage 204, the instruction stored in register 310 is decoded and, if applicable, register file 314 is accessed to retrieve operands specified in the instruction. Immediate values specified in the instruction may be stored in register 320. Alternatively, register 320 may store values retrieved from register file 314. Mux 316 determines whether values from register file 314 or immediate values in the instruction are to be forwarded to register 322. In an example, the header register file 140 is used as a locally cached copy of header memory 114. Headers in the header register file 140 are provided by, for example, scheduler 190 which fetches a header for a packet from header RAM 114 or packet memory 142. Caching headers in header register file 140 gives packet processors 110 direct access to the much faster header register file 140 instead of fetching headers from the slower header memory 114. If a header field is to be retrieved from the header register file 140, then a request is made to the header register file 140 using an offset or address that is provided using register 318. In an example, commands to retrieve or update header fields in the header register 140 are stored in register 318 by the decode stage 204 and are executed in the execute stage 206.

Execute stage 206 includes mux 324, branch register 326, header register file 140, a first arithmetic logic unit (ALU) 330, register 332, conditional branch logic 331 and packet processing logic blocks 300. In execute stage 206, the instruction fetched in instruction fetch stage 202 and decoded in stage 204, is executed. Mux 324 selects with immediate value stored in value 320 and a value stored in register 322. Branch register 326 may further provide variables for branch selection to first ALU 330 and conditional branch logic 331. First ALU 330 executes instructions, for example, arithmetic instructions. The results of the execution are stored in register 332. The result of execution of an instruction by first ALU 330 may be a jump target address which is fed back to mux 312 under the control of conditional branch logic 331 that evaluates conditional branches. Conditional branch logic 331 may update or select the next instruction for program counter 302 to fetch by providing a select signal to mux 312. The result of execution can also be an intermediate result, that is used as an input to the second ALU 334 that supports aggregate commands including commands that may need to be executed in two or more clock cycles.

According to an embodiment of the invention, packet processing logic blocks 300 execute custom instructions that are designed to speedup packet processing functions as will be further described below. The instruction set architecture implemented by packet processing logic blocks 300 is referred to as Parallel and Adaptive Long Instruction Set Architecture (PALADIN). According to an embodiment of the invention, first ALU 330 or packet processing logic blocks 300 selectively assigns operations for selected packet processing functions to custom hardware acceleration blocks 126a-n.

In memory access and second execute stage 208, memory is accessed for either loading data or for storing data. For example, results from store memory operations or custom hardware acceleration blocks 126a-n may be stored in Shared Data RAM (SDRAM) 336 or Private Data RAM (PDRAM) 338. For load operations, the data fetched from the PDRAM 338 or SDRAM 336 is stored in register 344. The stored data is written back to the register file 314 by the write back stage 210. In an example, instructions that require only one clock cycle for completion are processed by first ALU 330. For the execution of single clock cycle instructions, the second ALU 334 may be used as a passive element that directs the results produced by first ALU 330 for write back to register file 314. Some PALADIN instructions that provide versatile functionality for packet processing operations may take two or more cycles to execute. For the processing of such instructions, intermediate results produced in the execute stage 206 are provided as inputs to the second ALU 334 of the second execute stage 208. The second ALU 334 generates the final results and directs the final results to register file 314 for write back.

In write back stage 210, data fetched from the private data RAM 338 or the shared data RAM 336 is directed back to the register file 314. Mux 340 selects the data from SDRAM 336 or PDRAM 338 and stores the selected value, for example a value from a load operation, in register 344. In the write back stage 210, the selected data is written back to register file 314.

The custom instructions to aid in packet processing as implemented by packet processing logic blocks 300 are described below.

### Parallel and Long Adaptive Instruction Set Architecture (PALADIN)

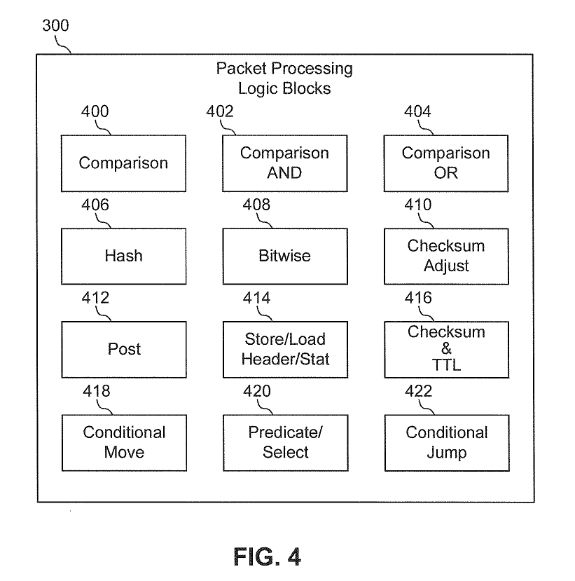

Provided below are instructions from PALADIN that are designed to speed up packet processing. The instructions described below allow for complex packet processing operations to be performed with relatively fewer instructions and clock cycles. In an embodiment, these instructions are implemented as hardware based packet processing logic blocks 400. FIG. 4 illustrates exemplary packet processing logic blocks 300 according to an embodiment of the invention. The packet processing logic blocks 300 include a comparison block 400, a comparison AND block 402, a comparison OR block 404, a hash logic block 406, a bitwise logic block 408, a checksum adjust logic block 410, a post logic block 412, a store/load header/status logic block 414, a checksum and time to live (TTL) logic block 416, a conditional move logic block 418, a predicate/select logic block 420 and a conditional jump logic block 422. These instructions executed by the packet processing logic blocks 300 reduce code density while speeding up packet processing times. For example, complex if-then-else selections, predicate/select operations, data moving operations, header and status field modifications, checksum modifications etc. can be performed with fewer instructions using the ISA provided below.

### Aggregated Comparison, Comparison OR and Comparison AND Instructions Aggregated Comparison OR

Example syntax of the “Comparison OR” (cmp_or) instruction is provided below:

cmp_or bd0, (op3, rs0, rs1) op2 (op3′, rs2, rs3)

Upon receiving the cmp_or instruction, the comparison OR logic block 404 performs the operation specified by op3′ on operands rs2 and rs3 to generate a first result and the operation specified by op3 on operands rs0 and rs1 to generate a second result. The comparison OR logic block 404 performs a third operation specified by op2 on the first and second results to generate a third result. The comparison OR logic block 404 performs a logical OR operation of the third result and a previously stored value in bd0 to generate a fourth result that is stored back into bd0. Thus, the single comparison OR instruction can perform multiple operations on multiple operand and aggregate results using a logical OR operation.

In an embodiment, op3′ and op3 are one of a no-op, an equal-to, a not-equal-to, a greater-than, a greater-than-equal-to, a less-than and a less-than-equal-to operation. In an embodiment, op2 is one of a no-op, logical OR, logical AND, and mask operations. It is to be appreciated that op3 and op3′ may be the same operation. A “mask operation” is similar to logical AND between two operands and results in stripping selective bits from a field. For example, 0x0110 mask 0x1100 results in 0x0100. A “mask” operand is an operand used to mask or “strip” bits from another operand.

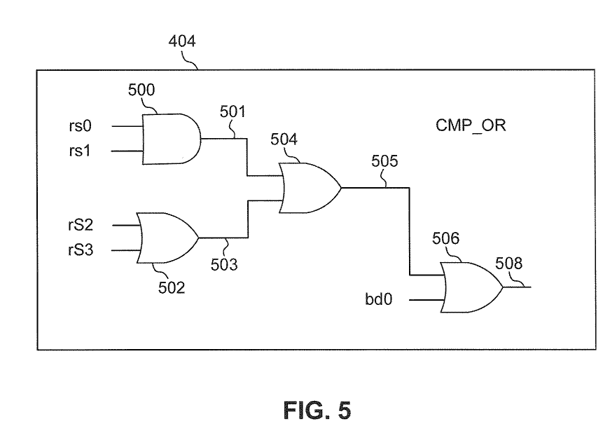

FIG. 5 illustrates an example implementation of the comparison OR logic block 404 in further detail. In this example, the comparison OR logic block 404 includes AND gate 500 and OR gates 502, 504 and 506.

FIG. 5 illustrates the execution of the following instruction:

cmp_or bd0, (AND, rs0, rs1) op2 (OR, rs2, rs3)

OR gate 502 performs a logical OR of rs2 and rs3 to generate a first result 503. AND gate 500 performs a logical AND of rs0 and rs1 to generate second result 501. OR gate 504 performs a logical OR of the first result 503 and the second result 501 to generate a third result 505. OR gate 506 performs a logical OR of the third result 505 and bd0 to generate the fourth result 508.

### Aggregated Comparison AND

Example syntax of the “Comparison AND” (cmp_and) instruction is provided below:

cmp_and bd0, (op3, rs0, rs1) op2 (op3′, rs2, rs3)

The comparison AND logic block 402, upon receiving the cmp_and instruction, performs the operation specified by op3′ on operands rs2 and rs3 to generate a first result. The comparison AND logic block 402 performs the operation specified by op3 on operands rs0 and rs1 to generate a second result and a third operation specified by op2 on the first and second results to generate a third result. The comparison AND logic block 404 performs a logical AND operation with the third result and a value stored in bd0 to generate a fourth result that is stored back into bd0.

In an embodiment, op3′ and op3 are one of a no-op, an equal-to, a not-equal-to, a greater-than, a greater-than-equal-to, a less-than and a less-than-equal-to operation. It is to be appreciated that op3 and op3′ may be the same operation. In an embodiment, op2 is one of a no-op, logical OR, logical AND, and mask operations.

### Aggregated Comparison

Example syntax of the “comparison” (cmp) instruction is shown below.

cmp bd0, (op3, rs0, rs1) op2 (op3′, rs2, rs3)

The comparison logic block 400, upon receiving the cmp instruction, performs the operation specified by op3′ on operands rs2 and rs3 to generate a first result. The comparison logic block 400 performs the operation specified by op3 on operands rs0 and rs1 to generate a second result and a third operation specified by op2 on the first and second results to generate a third result that is stored into bd0.

Examples of syntax and assembly code for the cmp, cmp_or and cmp_and instructions are provided below in table 1.

TABLE 1

| op | op2 | p3 | semantics/assembly |
|---|---|---|---|
| 0x01 | 0x0 (nop) | op3 | bd0 ← (rs0, op3, rs1/Immed0) , bd1 ← (rs2, op3, rs3/Immed1) |
| (cmp) | | | cmp bd0, (op3, rs0 ,rs1/Immed0) [, bd1, (op3, rs2 , |
| | | | rs3/Immed1) ] |
| | 0x1 (or) | | bd0 ← (rs0, op3, rs1/immed0) \| (rs2, op3, rs3/Immed1) |
| | | | cmp bd0, (op3, rs0, rs1/immed0) or (op3, rs2, rs3/Immed1) |
| | 0x2 (and) | | bd0 ← (rs0, op3, rs1/immed0 ) & (rs2, op3, rs3/Immed1) |
| | | | cmp bd0, (op3, rs0, rs1/immed0) and (op3, rs2, rs3/Immed1) |
| | 0x3 (mask) | | bd0 ← (rs0 & mask) op3 (rs1/Immed0 & mask) |
| | | | cmp bd0, (op3, rs0 , rs1/Immed0) mask mask/rs2 |
| 0x02 | 0x0 (nop) | op3 | bd0 ← bd0 \| ((op3, rs0, rs1/immed0) |
| (cmp_or) | | | cmp_or bd0, (op3, rs0, rs1/immed0) |
| | 0x01 (or) | | bd0 ← bd0 \| ((op3, rs0, rs1/immed0) \| (op3, rs2, rs3/Immed1)) |
| | | | cmp_or bd0, (op3, rs0, rs1/immed0) or (op3, rs2, rs3/Immed1) |
| | 0x02 (and) | | bd0 ← bd0 \| ((op3, rs0, rs1/immed0) & (op3, rs2, rs3/Immed1)) |
| | | | cmp_or bd0, (op3, rs0, rs1/immed0) and (op3, rs2, rs3/Immed1) |
| | 0x3 (mask) | | bd0 ← bd0 \| ((rs0 & mask) op3 (rs1/Immed0 & mask)) |
| | | | cmp_or bd0, (op3, rs0 , rs1/Immed0) mask mask/rs2 |
| 0x03 | 0x0 (nop) | op3 | bd0 ← bd0 & ((rs0, op3, rs1/immed0) |
| cmp_and | | | cmp_and bd0, (op3, rs0, rs1/immed0) |
| | 0x01 (or) | | bd0 ← bd0 & ((rs0, op3, rs1/immed0) \| (rs2, op3, rs3/Immed1)) |
| | | | cmp_and bd0, (op3, rs0, rs1/immed0) or (op3, rs2, rs3/Immed1) |
| | 0x02 (and) | | bd0 ← bd0 & ((rs0, op3, rs1/immed0) & (rs2, op3, rs3/Immed1)) |
| | | | cmp_and bd0, (op3, rs0, rs1/immed0) and (op3, rs2, rs3/Immed1) |
| | 0x3 (mask) | | bd0 ← bd0 & ((rs0 & mask) op3 (rs1/Immed0 & mask)) |
| | | | cmp_and bd0, (op3, rs0, rs1/immed0) mask mask/rs2 |

Example definitions of op3/op3′ are provided in table 2 below:

TABLE 2

| op3/op3′ | semantics/assembly |
|---|---|
| 0x0 (nop) | |
| 0x1 (eq) | eq def= bd0 = (rs0 == rs1 [/immed0]) |
| 0x2 (neq) | neq def= bd0 = (rs0 != rs1 [/immed0]) |
| 0x3 (gt) | gt def= bd0 = (rs0 > rs1 [/immed0]) |
| 0x4 (ge) | ge def= bd0 = (rs0 >= rs1 [/immed0]) |
| 0x5 (lt) | lt def= bd0 = (rs0 < rs1 [/immed0]) |
| 0x6 (le) | le def= bd0 = (rs0 <= rs1 [/immed0]) |

It is to be appreciated that op3 and op3′ may be the same or different operations in an instruction. Operands rs0, rs1, rs2 and rs3 may be operands obtained from a register file, from the fields of a packet header or may be immediate values. Operands rs0, rs1, rs2 and rs3 may be accessed via direct, indirect, immediate addressing or any combinations thereof.

### Bitwise Operations

Example syntax of a “bitwise” instruction is provided below:

bitwise rd0, (rs0, op3, rs1) op2 (rs2, op3′, rs3)

Upon receiving the bitwise instruction, the bitwise logic block 408 performs the operation specified by op3′ on operands rs2 and rs3 to generate a first result and the operation specified by op3 on operands rs0 and rs1 to generate a second result. The bitwise logic block 408 performs a third operation specified by op2 on the first and second results to generate a third result that is stored into rd0.

In an embodiment, op3′ and op3 are one of a logical NOT, logical AND, logical AND, Logical XOR, shift left and shift right. It is to be appreciated that op3 and op3′ may be the same operation. In another embodiment, op2 is one of a logical OR, logical AND, shift left, shift right and add operations. Examples of syntax and assembly code for the bitwise instruction are provided below in table 3.

TABLE 3

| op | op2 | op3 | semantics/assembly |
|---|---|---|---|
| 0x04 | 0x1 (\|) | 0x01 (~) | rd0 ← (rs0, op3, [rs1/Immed0]) or (rs2, op3, [rs3/Immed1]) |
| bitwise | | 0x02 (&) | bitwise rd0, (op3, rs0, rs1/Immed0) \| (op3, rs2, rs3/Immed1) |
| | | 0x03 (\|) | bitwise rd0, (op3, rs0, rs1/Immed0) \| rs3/Immed1 |
| | | 0x04 (\hat{ }) | |
| | | 0x05 (>>) | |
| | | 0x06 (<<) | |
| | 0x02 (&) | 0x01 (~) | rd0 ← (rs0, op3, [rs1/Immed0]) and (rs2, op3, [rs3/Immed1]) |
| | | 0x02 (&) | bitwise rd0, (op3, rs0, rs1/Immed0) & (op3, rs2, rs3/Immed1) |
| | | 0x03 (\|) | bitwise rd0, (op3, rs0, rs1/Immed0) & rs3/Immed1 |
| | | 0x04 (\hat{ }) | |
| | | 0x05 (>>) | |
| | | 0x06 (<<) | |
| | 0x4 | | (Reserved) |
| | 0x5 (>>) | 0x01 (~) | rd0 ← (rs0, op3, [rs1/Immed0]) >> (rs2, op3, [rs3/Immed1]) |
| | | 0x02 (&) | bitwise rd0, (op3, rs0, rs1/Immed0) >> (op3, rs2, rs3/Immed1) |
| | | 0x03 (\|) | bitwise rd0, (op3, rs0, rs1/Immed0) >> rs3/Immed1 |
| | | 0x04 (\hat{ }) | |
| | | 0x05 (>>) | |
| | | 0x06 (<<) | |
| | 0x6 (<<) | 0x01 (~) | rd0 ← (rs0, op3, [rs1/Immed0]) << (rs2, op3, [rs3/Immed1]) |
| | | 0x02 (&) | bitwise rd0, (op3, rs0, rs1/Immed0) << (op3, rs2, rs3/Immed1) |
| | | 0x03 (\|) | bitwise rd0, (op3, rs0, rs1/Immed0) << rs3/Immed1 |
| | | 0x04 (\hat{ }) | |
| | | 0x05 (>>) | |
| | | 0x06 (<<) | |
| | 0x7 (add) | 0x01 (~) | rd0 ← (rs0, op3, [rs1/Immed0]) + (rs2, op3, [rs3/Immed1]) |
| | | 0x02 (&) | bitwise rd0, (op3, rs0, rs1/Immed0) + (op3, rs2, rs3/Immed1) |
| | | 0x03 (\|) | bitwise rd0, (op3, rs0, rs1/Immed0) + rs3/Immed1 |
| | | 0x04 (\hat{ }) | |
| | | 0x05 (>>) | |
| | | 0x06 (<<) | |

Examples of op3/op3′ are provided below in table 4:

TABLE 4

| op3 | semantics/assembly |
|---|---|
| 0x0 (nop) | |
| 0x1 (~) | not def= rd0 = ~ (rs1/immed0) |
| 0x2 (&) | and def= rd0 = (rs0 & rs1/immed0) |
| 0x3 (\|) | or def= rd0 = (rs0 \| rs1/immed0) |
| 0x4 (\hat{ }) | xor def= rd0 = (rs0 \hat{ } rs1/immed0) |
| 0x5 (>>) | shift-r def= rd0 = (rs0 >> rs1/immed0) |
| 0x6 (<<) | shift-l def= rd0 = (rs0 << rs1/immed0) |

### HASH Operations

Example syntax of the “Hash” instruction is shown below.

Hash crcX [##]<-rd0, (rs0, rs1, rs2, rs3) [<<n] [+base]

Upon receiving the hash instruction, the hash logic block 406 computes a remainder of a plurality of values specified by rs0, rs1, rs2 and rs3 using a Cyclic Redundancy Check (CRC) polynomial and adds a default base address to the remainder to generate a first result. The first result is shifted by n to generate a hash lookup value for, for example, an Address Resolution Lookup (ARL) table for Layer-2 (L2) switching. In an example, an optional base address specified by “base” in the above syntax is added to the hash lookup value as well. The type of CRC used is a design choice and may be arbitrary. For example, X in the above syntax for the hash instruction may be 6, 7 or 8 resulting in a corresponding CRC 6, CRC 7 or CRC 8 computation.

An example format of the Hash instruction is shown below in table 5.

TABLE 5

| | 77:66 | | | 65:58 | | 57:50 | 49:46 | | 45:43 | 42:38 | 37:33 | 32:25 | 24:17 | 16:13 | 12:5 | 4:0 |
|---|---|---|---|---|---|---|---|---|---|---|---|---|---|---|---|---|
| Fmt1 | op_{8b} | tid | op2 | op3 | rd0_{5b} | rs0_{5b} | 0 | k | n | base | rs1_{5b{} | rd1 (rsvd) | rs2_{5b} | 0 | base[10:0] | rs3_{5b} |
| | | | | | | | | | | [15: | | | | | | |
| | | | | | | | | | | 11] | | | | | | |

Examples of op2/op3 and other operand values for the hash instruction in table 5 are provided in table 6 below:

TABLE 6

| | semantics/assembly |
|---|---|
| op3 | |
| 0x1 (crc6) | calculate the remainder by CRC6 |
| 0x2 (crc7) | calculate the remainder by CRC7 |
| 0x3 (crc8) | calculate the remainder by CRC8 |
| op2 | |
| 0x07 | Add the supplement base address to the result. |
| << n | Left shift the hash value by n bits, 0<n <=4 |
| k | When k is 0, the CRC logic starts with an initial state of 0; |
| | otherwise, the initial state is the last state after the preceding |
| | hash command. |
| base | An optional base address is added to the final result. |

In an example, 64 bits of data can be entered in each hash instruction. For Level 2 L2 ARL lookup, the lookup key comprises 48 bits of Media Access Control (MAC) Destination Address (DA) and 12 bits of VLAN identification, which can be specified in one hash instruction. To generate a NAT table lookup value, the key may include Source IP address (SIP), Destination IP address (DIP), Source Port Number (SP), Destination Port Number (DP) and protocol type (for example, Transmission Control Protocol (TCP) or User Datagram Protocol (UDP)).

If the key is longer than 64 bits, consecutive hash commands may be issued as in the following example:

hash crc6 r0, (r1, r2, r3, r4)

hash crc6 ## r15, (r5, r6, r7, r8)<<2+base

The first command will reset the CRC logic with an initial state of 0, and take in (r1, r2, r3, 4) as the inputs. The second command, which is annotated with the “##” continuation directive, takes in additional inputs (r5, r6, r7, r8) for the calculation of the final CRC remainder based on results of the prior hash instruction. The hash functions are further optimized to allow the calculated value to be shifted by n bits and added to a base address. This optimization is useful, for instance, when an entry of a hash table is of 2ⁿ half-words. A calculated hash index of value of “h” specifies the table entry, and (h<<n)+base subsequently points to the memory location where the table entry starts.

### Packet Field Handling Operations

Packet handling instructions are optimized to adjust certain packet fields such as checksum and time to live (TTL) values. Example syntax of a “checksum addition” (csum_add) instruction is provided below:

csum_add rd0, (rs0, rs1), rs3

In the above instruction, rs0 is a current checksum value, rs1 is an adjustment to the current checksum value, rs3 is the protocol type and rd0 is the new checksum value. Upon receiving the csum_add instruction, the checksum adjust logic block 410 updates the current checksum value (rs0) based on the adjustment value (rs1) and the type of protocol (rs3) associated with the current checksum value to generate the new checksum value and store it in rd0.

Example syntax of an “Internet Protocol (IP) Checksum and Time To Live (TTL) adjustment” (ip_checksum_ttl_adjust) instruction is provided below:

ip_checksum_ttl_adjust rd0, (rs0, rs1), rd1

In the above instruction, rs0 is the current Internet Protocol (IP) checksum value, rs1 is the current Time To Live (TTL) value, rd0 is the new checksum value and rd1 is the new TTL value.

Upon receiving the ip_checksum_ttl_adjust instruction, the checksum and TTL adjust logic block 416 generates a new TTL value based on the current TTL value (rs1) and stores it in rd1. The checksum and TTL adjust logic block 416 also updates the current checksum value (rs0) based on the new TTL value to generate the new checksum value and stores it in rd0.

Example syntax and assembly code for the csum_add and the ip_checksum_ttl_adjust commands is shown below in table 7.

TABLE 7

| op | op2 | op3 | semantics/assembly |
|---|---|---|---|
| 0x07 | 0x0 | 0x0 (nop) | |
| (pkt) | | 0x1 (csum_add) | csum_add rd0, (rs0, rs1/immed0), rs3/immed1 |

| | |
|---|---|
| Input: | rs0: old checksum |
| | rs1/immed0: adjustment |
| | rs3/immed1: protocol type |

| | |
|---|---|
| | output: rd0: new checksum |
| | csum_add( ): |
| | if (old_checksum ==0 && protocol_type == UDP) |
| | rd0 ← 0 // optional UDP checksum |
| | else { |
| | new_checksum = ~(~old_csum + adjust_csum); |
| | /* check special case for UDP ip_proto → 17 */ |
| | if (new_checksum == 0 && protocol_type == UDP) |
| | new_checksum = 0xffff; |
| | csum_add: rd0 ← new_checksum |
| | } |
| 0x02 (ip_checksum_ttl_adjust) | ip_checksum_ttl_adjust rd0, (rs0, rs1/immed0), rd1 |

| | |
|---|---|
| input: | rs0: old IP checksum |
| | rs1/immed0: old TTL |
| output: | rd0: new checksum |
| | rd1: new TTL |

```
  ip_decrease_ttl( ):
new_checksum = rs0 + 0x0100;
  if (new_checksum >= 0xffff) new_checksum =
  new_checksum + 0x01; // carry
  rd0 ← new_checksum[15:0];
  rd1 ← old TTL − 1
```

### Post Command

Example syntax of the post instruction is shown below:

post asyn uid, ctx0, rs0, rs1, ctx1, rs2, rs3

In the post command above:
the asyn field indicates whether a packet processor 100 should stall while waiting for a custom hardware acceleration block 126 to complete an assigned task,
the uid field identifies the custom hardware acceleration block 126 to which the task is assigned,
the ctx0 and ctx1 fields may include context sensitive information that is to be interpreted by a target custom hardware block 126. For example, the ctx0 and ctx1 may include information that indicates the operation(s) that a target custom hardware acceleration block 126 is to perform,
rs0, rs1, rs2 and rs3 may be used to convey inputs that are to be used by a target custom hardware acceleration block 126.

Upon receiving the post instruction, the post logic block 412 assigns a task to a target custom hardware acceleration block 126. It is to be appreciated that the number of ongoing tasks and the number of source and destination registers that may be assigned to a custom hardware acceleration block 126 is a design choice and may be arbitrary. An example use of the instruction to move data from global memory to local memory is shown below:

post asyn UID_uDM, GM2LM, r12, LMADDR_VLAN, 2, r0, r0

In the above command, the uid field is UID_uDM which specifies a “micro data mover” as the custom hardware acceleration block 126 that is to perform the required task specified in the ctx0 and ctx1 fields. The ctx0 field is GM2LM which indicates that the micro data mover is move data from global memory (such as shared memory 106) to local memory (such as private memory 108). R12 is the address in shared memory 106 from which data is to be moved to LMADD_VLAN which is the address in private memory 108. The value of the ctx1 field is 2 which indicates the length of the data to be moved. Fields rs2 and rs3 are assigned register rs0 (which is always 0) as a filler since they are not required to have values for this task.

### Predicate and Select Instructions

Predicate and select instruction are designed to be used in conjunction for complex if-then selection processes. Example syntax of the predicate and select instructions is provided below:

Predicate rd0, (mask0, mask1, mask2, mask3)

Select rd0, (rs0, rs1, rs2, rs3)

The predicate instruction is paired with the select instruction to realize up to 1-out-of-5 conditional assignments. The predicate and select instructions are to be used in conjunction. Each predicate instruction can carry up to four 8-bit mask fields. Each mask field in the predicate instruction specifies the boolean registers that must be asserted as “true” in order for its corresponding predicate to be set to a value of 1. For example, a mask of 0x3 means that the corresponding predicate is true if the boolean registers br0 and br1 are both true (e.g. have a value of 1). The subsequent select instruction assigns the first source register whose predicate is true to the destination register. The rd0 register of the predicate instruction holds the default value. If none of the conditions specified in the predicate instruction are true, the default value is returned as the outcome for the next select instruction. The following code illustrates an example of the predicate and select instructions:

predicate r5, (0x01, 0x03, 0x02, 0x06)

select r10, (r1, r2, r3, r4)

The above instructions are equivalent in logic to:

If (boolean register br0 is true) then r10=r1;

else if (both boolean registers br0 and br1 are true) then r10=r2;

else if (boolean register br1 is true) then r10=r3;

else if (both boolean registers br2 and br1 are true) then r10=r4;

else r10=r5.

Thus, the predicate and select instructions can simplify and condense multiple if-then-else conditions into two instructions. In an example, four ephemeral predicate registers (not shown) are provided for each packet processor 110 to support predicate and select commands. These ephemeral predicate registers are not directly accessible by instructions other than the predicate and select instructions. Values in the predicate register are set when a predicate instruction is issued.

### Conditional Jump

When handling branch instructions, traditional general purpose processors stall until the branch is resolved. Execution is then either resumed at the next instruction (if the branch is not taken), or at the jump target (if the branch is taken). In order to increase performance, general purpose processors use complex logic for speculative execution and instruction rollback under incorrect speculation, which results in complex designs and increased power and chip real estate requirements. Packet processors 110 as described herein avert the complexity of speculative execution by using conditional jumps as described below which evaluate multiple jumps and conditions in a single instruction.

Example syntax of the conditional jump (jc) instruction is shown below:

jc (label0, condition0), (label1, condition1), (label2, condition2), (label3, condition3)

Upon receiving a conditional jump instruction, the conditional jump logic block 422 adjusts a program counter (pc) 302 of a packet processor 110 to a first location of multiple locations in program code stored in instruction memory 112 based on whether a corresponding first condition of multiple conditions is true. For example, the jc instruction is executed as follows:

pc<-label0 if (condition0 is true), or

pc<-label1 if (condition1 is true), or

pc<-label2 if (condition2 is true), or

pc<-label3 if (condition3 is true).

Thus the conditional jump as described herein can evaluate multiple jump conditions using a single conditional jump instruction.

Another example of the conditional jump instruction is the relative conditional jump instruction provided below.

jcr (offset°, mask0), (offset1, mask1), (offset2, mask2), (offset3, mask3)

The relative conditional jump instruction adds an offset to the program counter to determine the location in program code to jump to. Upon execution of the jcr instruction, the following steps are performed by the conditional jump logic block 422::

pc<-pc+offset0 if (mask0!=0 && (br[7:0] & mask0)==mask0),
pc+offset1 if (mask1!=0 && (br[7:0] & mask1)==mask1),
pc+offset2 if (mask2!=0 && (br[7:0] & mask2)==mask2), or
pc+offset3 if (mask3!=0 && (br[7:0] & mask3)==mask3).

### Conditional Move

Example syntax of the conditional move instruction is shown below:

cmv rd0, (rs1, rs2) cond bd0

While predicate and select instructions support complex conditional assignments, they are not optimized for the simple if-else conditional move cases which typically take up to three instructions in conventional processors. In conventional processors, a first instruction is required to set a boolean value in a boolean register bd0. A second instruction is required to set the predicate and a third instruction is required to execute selection based on a value in bd0. According to an embodiment of the invention, to arrive at an optimal design, a dedicated conditional move instruction is provided to reduce the number of instructions to one.

Upon receiving the conditional move instruction, the conditional move logic block 418 moves the value specified by rs1 to rd0 if the boolean value in bd0 is true and moves the value in rs2 to rd0 if the boolean value in bd0 is false. Thus the number of instructions to execute a conditional move is reduced to one.

Header and Status instructions

Header and status instructions, as described herein, can move multiple packet headers and packet status fields to/from header memory 114 and status queue 125 in a single instruction. The header fields are header of incoming packets The status fields indicate control information such as location of a destination port for a packet, length of a packet and priority level of a packet. It is to be appreciated that the status fields may include other packet characteristics in addition to the ones described above.

The “load header” instruction has the following syntax:

ld_hdr (rd0, rs0/offs0), (rd1, rs1/offs1), (rd2, rs2/offs2), (rd3, rs3/offs3)

Upon execution of the load header instruction, the header and status logic block 414 moves data from the specified locations in header memory 114 to specified registers in register file 314. For example, header and status logic block 414 performs the following operation:

rd0<-HDR[rs0/offs0]

rd1<-HDR[rs1/offs1]

rd2<-HDR[rs2/offs2]

rd3<-HDR[rs3/offs3]

where HDR is the header memory 114 and rs0/offs0, rs1/offs1, rs2/offs2 and rs3/offs3 specify the locations in header memory 114 from which data is to be loaded.

The “store header” instruction has the following syntax:

st_hdr (rd0, rs0/offs0), (rd1, rs1/offs1), (rd2, rs2/offs2), (rd3, rs3/offs3)

Upon execution of the store header instruction, the header and status logic block 414 performs the following operation:

HDR[rs0/offs0]<-rd0

HDR[rs1/offs1]<-rd1

HDR[rs2/offs2]<-rd2

HDR[rs3/offs3]<-rd3

where rs0/offs0, rs1/offs1, rs2/offs2 and rs3/offs3 specify the locations in header memory 114 from which data is to be stored from the corresponding registers.

The “load status” instruction has the following syntax:

ld_stat (rd0, rs0/offs0), (rd1, rs1/offs1), (rd2, rs2/offs2), (rd3, rs3/offs3)

Upon execution of the load status instruction, the header and status logic block 414 performs the following operation:

rd0<-STAT[rs0/offs0]

rd1<-STAT[rs1/offs1]

rd2<-STAT[rs2/offs2]

rd3<-STAT[rs3/offs3]

where rs0/offs0, rs1/offs1, rs2/offs2 and rs3/offs3 specify the locations in status queue 125 from which data is to be stored into the corresponding registers.

The “store status” instruction has the following syntax:

st_stat (rd0, rs0/offs0), (rd1, rs1/offs1), (rd2, rs2/offs2), (rd3, rs3/offs3)

Upon execution of the store status instruction, the header and status logic block 414 performs the following operation:

STAT[rs0/offs0]<-rd0

STAT[rs1/offs1]<-rd1

STAT[rs2/offs2]<-rd2

STAT[rs3/offs3]<-rd3

where rs0/offs0, rs1/offs1, rs2/offs2 and rs3/offs3 specify the locations in status queue 125 into which data is to be stored from the corresponding registers.

The “move header right” instruction (mv_hdr_r) has the following syntax:

mv_hdr_r n, offs0

Upon execution of the move header right instruction, the header and status logic block 414 shifts a header to the right by n bytes, starting at the specified offset (offs0). In an example, this command can be used to make space to insert VLAN tags or a PPPoE (Point-to-Point over Ethernet) header into an existing header.

The “move header left” instruction (mv_hdr_1) has the following syntax:

mv_hdr_1 n, offs0

Upon execution of the move header left instruction, the header and status logic block 414 shifts a header to the left by n bytes, starting at the specified offset (offs0). In an example, this command can be used to adjust the header after removing VLAN tags or a PPPoE header from an existing header.

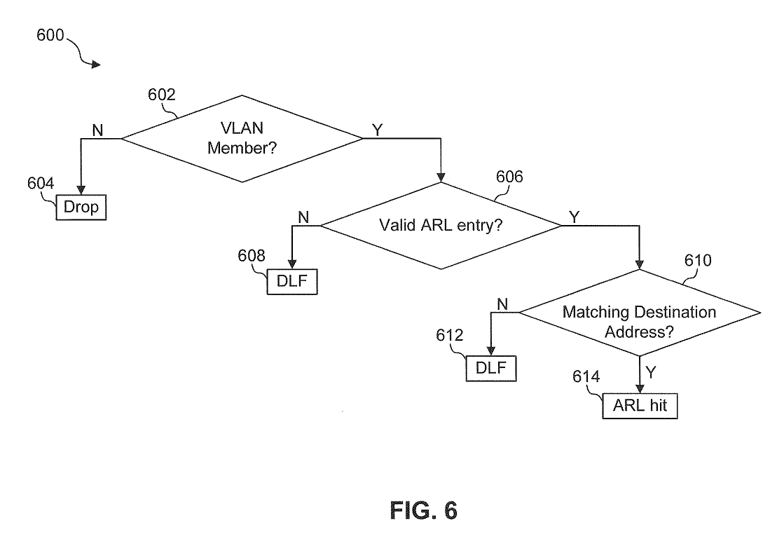

Instructions such as conditional jump instructions, bitwise instructions, comparison and comparison_or instructions are especially useful in complex operations such as Layer 2 (L2) switching. The flowchart in FIG. 6 illustrates an example flowchart to process a packet during L2 switching.

In step 602, it is determined whether a VLAN ID in the received packet is in a VLAN table. If the VLAN ID is not found in the VLAN table then the packet is dropped in step 604. If the VLAN ID is found, then the process proceeds to step 606.

In step 606, if the packet has a corresponding entry in an ARL table then the process proceeds to step 608 where the packet is classified as a destination lookup failure (DLF). If the packet is classified as a DLF, then the packet is flooded to all ports that correspond to the packet's VLAN group. If the packet has a corresponding entry in an ARL table, then the process proceeds to step 610.

In step 610, if the MAC Destination Address (DA) in the ARL table is different from the MAC DA in the packet, then the packet is classified as a DLF in step 612 and is flooded to all ports that correspond to the packet's VLAN group.

If the MAC DA in the ARL table and the MAC DA in the packet match, then the packet is classified as an ARL hit in step 614 and is forwarded accordingly to the MAC DA.

Using the instructions described herein, the steps of flowchart 600 can be performed using fewer instructions than a processor that uses a conventional ISA. For example, the steps of flowchart 600 may be executed by the following instructions:

| | | |
|---|---|---|
| ld | r4, (r0, LMADDR_VLAN) | |
| bitwise | r5, (\|, r4, r0) mask 0x00ff | // port map from VLAN table |
| bitwise | r6, (>>, r4, 8) mask 0xff00 | // for untagged instructions |
| cmp | br0,(neq, r9, r5) mask r9 | // check if the packet is not in the |
| | | VLAN group |
| ld | r4, (r0, 4), r8, (r0, 7) | // load port map from the ARL-DA |
| | | entry |
| ld | r10, (r0, 2), r11, (r0, 1) | // load MAC addr[47:16] from the |
| | | ARL |
| ld | r12, (r0, 0), r7, (r0, 3) | // load MAC addr[15:0] and VLAND |
| | | ID from the ARL |
| cmp | br1, (neq, r8, 0x8000) mask 0x8000 | // check valid bit |
| cmp_or | br1, (neq, r10, r1) or (neq, r11, r2) | |
| cmp_or | br1, (neq, r12, r3) or (neq, r15, r7) | // aggregated cmp_or to determine if br1 |
| | | indicates that there is a DLF |
| jc | (clean_up_l2_and_drop, BR0), | // determines if there is a DLF or an ARL hit |
| | (DLF, BR1), (ARL_hit, BR7) | and jumps to the corresponding section of code |

Embodiments presented herein, or portions thereof, can be implemented in hardware, firmware, software, and/or combinations thereof. The embodiments presented herein apply to any communication system that utilizes packets for data transmission.

The representative packet processing functions described herein (e.g. functions performed by packet processors 110, custom hardware acceleration blocks 126, control processor 102, separator and scheduler 118, packet processing logic blocks 300 etc.) can be implemented in hardware, software, or some combination thereof. For instance, the method of flowchart 600 can be implemented using computer processors, such as packet processors 110 and/or control processor 102, packet processing logic blocks 300, computer logic, application specific circuits (ASIC), digital signal processors, etc., or any combination thereof, as will be understood by those skilled in the arts based on the discussion given herein. Accordingly, any processor that performs the signal processing functions described herein is within the scope and spirit of the embodiments presented herein.

Further, the packet processing functions described herein could be embodied by computer program instructions that are executed by a computer processor, for example packet processors 110, or any one of the hardware devices listed above. The computer program instructions cause the processor to perform the instructions described herein. The computer program instructions (e.g. software) can be stored in a computer usable medium, computer program medium, or any storage medium that can be accessed by a computer or processor. Such media include a memory device, such as instruction memory 112 or shared memory 106, a RAM or ROM, or other type of computer storage medium such as a computer disk or CD ROM, or the equivalent. Accordingly, any computer storage medium having computer program code that cause a processor to perform the signal processing functions described herein are within the scope and spirit of the embodiments presented herein.

### CONCLUSION

While various embodiments have been described above, it should be understood that they have been presented by way of example, and not limitation. It will be apparent to persons skilled in the relevant art that various changes in form and detail can be made therein without departing from the spirit and scope of the embodiments presented herein.

The embodiments presented herein have been described above with the aid of functional building blocks and method steps illustrating the performance of specified functions and relationships thereof. The boundaries of these functional building blocks and method steps have been arbitrarily defined herein for the convenience of the description. Alternate boundaries can be defined so long as the specified functions and relationships thereof are appropriately performed. Any such alternate boundaries are thus within the scope and spirit of the claimed embodiments. One skilled in the art will recognize that these functional building blocks can be implemented by discrete components, application specific integrated circuits, processors executing appropriate software and the like or any combination thereof. Thus, the breadth and scope of the present embodiments should not be limited by any of the above-described exemplary embodiments, but should be defined only in accordance with the following claims and their equivalents.

What is claimed is:

1. A processor, comprising:
an instruction memory; and
at least one execution unit configured to, upon receiving a single aggregate instruction from the instruction memory, perform a first operation on a first plurality of operands to generate a first result, perform a second operation on a second plurality of operands to generate a second result and perform a third operation on the first and second results to generate a third result.

2. The processor of claim 1, wherein the operands are based on one or more fields of a header of a packet received by the processor.

3. The processor of claim 1, wherein the single aggregate instruction is a bit-wise instruction.

4. The processor claim 1, wherein the first and second operations are one of logical NOT, logical AND, logical OR, logical XOR, shift right and shift left.

5. The processor of claim 1, wherein the third operation is one of logical OR, logical AND, addition, shift left and shift right.

6. The processor of claim 1, wherein the execution unit is configured to perform a fourth operation on the third result and a value stored in a specific memory location to generate a fourth result.

7. The processor of claim 6, wherein the single aggregate instruction is a comparison instruction.

8. The processor of claim 6, wherein the value stored in the specific memory location is a fourth result from a previous execution of the aggregate instruction.

9. The processor of claim 6, wherein the first and second operations are one of a no-op, an equal-to, a not-equal-to, a greater-than, a greater-than-equal-to, a less-than and a less-than-equal-to operation.

10. The processor of claim 6, wherein the third operation is one of a no-op, logical OR, logical AND, and mask operations.

11. The processor of claim 6, wherein the fourth operation is one of a logical OR and a logical AND.

12. A processor, comprising:
an instruction memory; and
an execution unit configured to, upon receiving a select instruction from the instruction memory that specifies a destination and a plurality of source values and a predicate instruction that specifies a default value and a plurality of mask values corresponding to the source values in the select instruction, assign a source value to the destination if a mask value corresponding to source value is true, and assign the default value to the destination if none of the mask values are true.

13. The processor of claim 12, wherein the operands are based on one or more fields of a header of a packet received by the processor.

14. The processor of claim 12, wherein the predicate instruction is before the select instruction in program order.

15. The processor of claim 12, wherein each mask value corresponds to boolean registers that have a value of 0 or 1.

16. A processor, comprising:
an instruction memory; and
at least one execution unit configured to update a current Time To Live (TTL) value and generate a new TTL value and to update a current checksum value based on the new TTL value to generate a new checksum value in response to a single checksum and TTL adjustment instruction from the instruction memory that includes:
a first field that provides the execution unit with the current checksum value, and
a second field that provides the processor with the current TTL value.

17. The processor of claim 16, wherein the operands are based on one or more fields of a header of a packet received by the processor.

18. A processor, comprising:
an instruction memory; and
at least one execution unit configured to generate a hash value by computing a remainder of a plurality of values using a Cyclic Redundancy Check (CRC) polynomial, adding a base address to the remainder to generate a first result, shifting the first result by a first value to generate a second result and adding an optional base address to the second result, in response to a single hash instruction from the instruction memory that includes:
a first field that provides the execution unit with a type of CRC polynoial for calculating the remainder,
a second field that provides the execution unit with the destination location,
a third field that provides the execution unit with the first value,
a fourth field that provides the execution unit with the optional base address, and
a plurality of fields that provide the execution unit with the plurality of values.

19. The processor of claim 18, wherein the hash instruction further comprises a fifth field that indicates whether the hash instruction is a continuation of a previous hash instruction.

20. A processor, comprising:
an instruction memory; and
at least one execution unit configured to assign a packet processing task to a hardware engine based on a context value, in response to a single post instruction from the instruction memory that includes:
a first field that indicates the task for the hardware engine;
a second field that identifies the hardware engine amongst a plurality of hardware engines;
a third field that that indicates whether the processor is to stall while waiting for the hardware engine to complete the task; and
a plurality of fields for source and destination values, wherein the source and destination values are based on header fields of a packet received by the processor.
